(19) United States
(12) Patent Application Publication
(10) Pub. No.: US 2009/0117701 A1
(43) Pub. Date: May 7, 2009

(54) METHOD FOR MANUFACTURING A MOS TRANSISTOR

(76) Inventors: Meng-Yi Wu, Kaohsiung County (TW); Kun-Hsien Lee, Tai-Nan City (TW); Cheng-Tung Huang, Kao-Hsiung City (TW); Wen-Han Hung, Kao-Hsiung City (TW); Shyh-Fann Ting, Tai-Nan City (TW); Li-Shian Jeng, Tai-Tung Hsien (TW); Chung-Min Shih, Tai-Nan City (TW); Yao-Chin Cheng, Hsinchu City (TW); Tzyy-Ming Cheng, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 11/934,053

(22) Filed: Nov. 1, 2007

(51) Int. Cl. H01L 21/336

(52) U.S. Cl. 438/305; 257/E21.409

(57) ABSTRACT

A method for manufacturing a MOS transistor includes performing a thermal treatment to repair damaged substrate before forming source/drain extension regions, accordingly negative bias temperature instability (NBTI) is reduced. Since the thermal treatment is performed before forming the source/drain extension regions, heat budget for forming the source/drain extension regions and junction depth and junction profile of the source/drain extension would not be affected. Therefore the provided method for manufacturing a MOS transistor is capable of reducing short channel effect and possesses a superior process compatibility.

### BACKGROUND OF THE INVENTION

1. Field of the Invention

The invention relates to a method for manufacturing a metal-oxide semiconductor (MOS) transistor, and more particularly, to a method capable of reducing negative bias temperature instability (NBTI) of a MOS transistor.

2. Description of the Prior Art

In accordance with a demand and tendency toward higher density and higher integration to integrated circuit and semiconductor devices, dimensions of semiconductor devices are continually shrunk. However, scales of the semiconductor devices are limited by process tolerance, electric characteristics directly related to the device itself, and requirement of high reliability to the integrated circuits.

Please refer to FIGS. 1-3, which are drawings illustrating a conventional method for manufacturing a MOS transistor. As shown in FIG. 1, a substrate 10 is firstly provided. The substrate 10 includes a polysilicon layer and a gate oxide layer formed thereon. For satisfying requirement of having high dielectric constant, stable thermal properties, high breakdown voltage, and small current leakage, a high temperature plasma nitridation process, such as a decoupled plasma nitridation (DPN), is performed to form a nitrogen-contained gate oxide layer 12. Then an ion implantation is performed to transfer the polysilicon layer into a doped polysilicon layer 14.

Please refer to FIG. 2. Next, an etching process is performed to remove a portion of the doped polysilicon layer 14 and a portion of the nitrogen-contained gate oxide layer 12 to form at least a gate 16 on the substrate 10. It is observed that the nitrogen-contained gate oxide layer 12 is damaged during the etching process, therefore a re-oxidation process, such as a rapid thermal oxidation (RTO) process, is performed to repair the damaged nitrogen-contained gate oxide layer 12.

Please still refer to FIG. 2. Then a liner 18 is formed on a sidewall of the gate 16, followed by performing an ion implantation process to form source/drain extension regions 20 having shallow junction in the substrate 10 at two sides of the gate 16, respectively.

Please refer to FIG. 3. A silicon nitride layer (not shown) is then deposited on the liner 18, and a dry etching process is performed to etch the silicon nitride layer and the liner 18 to form a spacer 22 on the sidewall of the gate 16. Finally, another ion implantation process is performed to form a source/drain 24 in the substrate 10 at two sides of the gate 16, respectively.

With the device scaling down, it's getting difficult to control the junction depth (Xⱼ) of the source/drain extension regions 20 and to reduce the access resistance. Therefore, heat used to diffuse the ions implanted into the substrate 10 to form the source/drain extension regions 20 is reduced in order to reduce short channel effect (SCE). Although such solution is able to reduce SCE, it generates another adverse influence on reliability of the MOS transistor.

As mentioned above, to achieve requirement of high dielectric constant, stable thermal properties, high breakdown voltage, and small current leakage, the nitrogen-contained gate oxide layer 12 is formed by a high temperature plasma nitridation process. It is noticeable that such process damages lattice in surface of the substrate 10. It also adversely affects interface between the nitrogen-contained gate oxide layer 12 and the substrate 10. Since heat budget is limited for reducing SCE, the limited heat is not sufficient to repair the damaged lattice in the surface of the substrate 10. In this circumstance, positive charges are trapped in the interface between the substrate 10 and the nitrogen-contained gate oxide layer 12. Therefore a negative shift of threshold voltage, namely negative bias temperature instability (NBTI), is resulted. Since NBTI causes negative threshold voltage shift, it adversely affects quality of the nitrogen-contained gate oxide layer 12 and that of the MOS transistor. It is well-known that the threshold voltage is required to be highly stable throughout lifetime of a circuit, especially of an analog circuit having high accuracy requirement, NBTI is deemed disadvantageous to performance of a circuit.

Therefore, it has become an incompatible subject in the conventional method for manufacturing a MOS transistor: in order to reduce SCE, the heat budget is reduced, thus energy is not sufficient to repair the damaged lattice in the surface of the substrate 10, and NBTI is worsened. But an over-budgeted heat introduced to repair the damaged lattice in the surface of the substrate 10 adversely affects junction depth and junction profile of the source/drain extension regions 20, thus worsen SCE. In fact, NBTI is one of the key limiting reliability factors in front-end-of-line process of advanced analog/mixed signal circuits, therefore a method that is able to solve the above-mentioned dilemmatic problem or is able to reduce both of SCE and NBTI is eagerly in need.

### SUMMARY OF THE INVENTION

It is therefore a primary objective of the claimed invention to provide a method capable of reducing both of SCE and NBTI, and thus improving reliability of a MOS transistor.

According to the claimed invention, a method for manufacturing a MOS transistor is provided. The method comprises providing a semiconductor substrate sequentially having a gate dielectric layer and a polysilicon layer formed thereon; performing a polysilicon doping process; performing a thermal treatment; performing an etching process to remove a portion of the gate dielectric layer and a portion of the polysilicon layer to form at least a gate after the thermal treatment; performing a first ion implantation process to form source/drain extension regions in the semiconductor substrate respectively at two sides of the gate; and performing a second ion implantation process to form a source/drain in the semiconductor substrate respectively at the two sides of the gate.

According to the claimed invention, another method for manufacturing a MOS transistor is provided. The method comprises providing a semiconductor substrate sequentially having a gate dielectric layer and a polysilicon layer formed thereon; performing an etching process to remove a portion of the gate dielectric layer and a portion of the polysilicon layer to form at least a gate; performing a re-oxidation process to repair the gate dielectric layer after the etching process; performing a thermal treatment after the etching process; performing a first ion implantation process to form source/drain extension regions in the semiconductor substrate respectively at two sides of the gate; and performing a second ion implantation process to form a source/drain in the semiconductor substrate respectively at the two sides of the gate.

According to the method for manufacturing a MOS transistor provided by the present invention, a thermal treatment is performed to repair the damaged lattice in the surface of the semiconductor substrate before forming the source/drain extension regions, therefore NBTI is reduced. Since the thermal treatment is performed before forming the source/drain extension regions, junction depth and junction profiles of the source/drain extension regions would not be affected. Therefore the method provided by the present invention is capable of reducing both of SCE and NBTI and processes a superior process compatibility.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 are drawings illustrating a conventional method for manufacturing a MOS transistor.

FIGS. 4-8 are schematic drawings illustrating a method for manufacturing a MOS transistor according to a first preferred embodiment of the invention.

FIGS. 9-13, which are schematic drawings illustrating a method for manufacturing a MOS transistor according to a second preferred embodiment of the invention.

FIG. 14 is a flowchart illustrating a method for manufacturing a MOS transistor provided by the present invention.

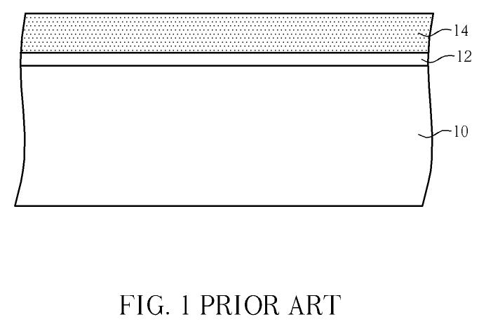

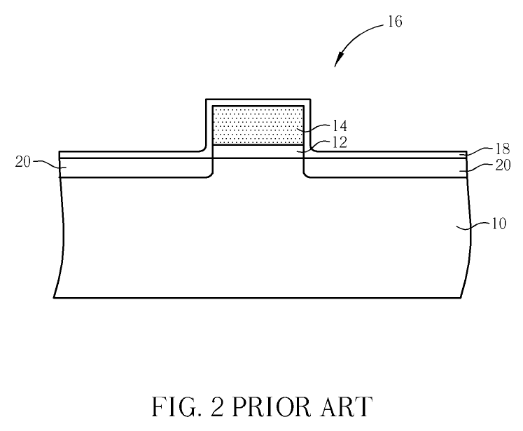

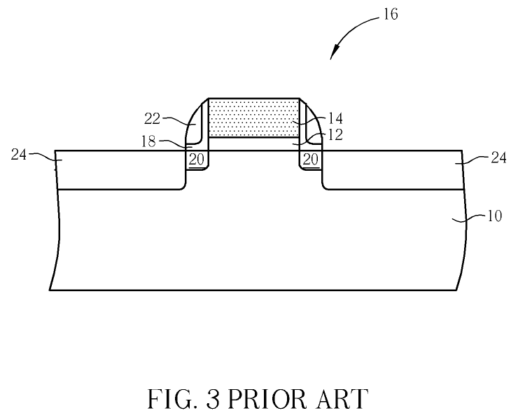

### DETAILED DESCRIPTION

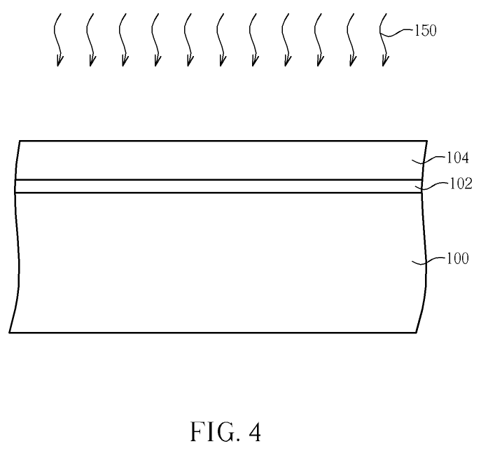

Please refer to FIGS. 4-8, which are schematic drawings illustrating a method for manufacturing a MOS transistor according to a first preferred embodiment of the present invention. As shown in FIG. 4, a semiconductor substrate 100 having a gate dielectric layer and a polysilicon layer 104 formed thereon is provided. For decreasing current leakage, offering a better barrier to boron, and improving performance of the transistor, nitrogen is implanted into the gate dielectric layer by a high temperature plasma nitridation process such as DPN, thus a nitrogen-contained gate dielectric layer 102 is obtained. It is noteworthy that the lattice in the surface of the semiconductor substrate 100 is often damaged, interface between the semiconductor substrate 100 and the nitrogen-contained gate dielectric layer 102 is adversely affected in such process, and consequently reliability of the transistor is adversely affected due to NBTI. Therefore, a thermal treatment 150 is performed to repair the damaged lattice in the surface of the semiconductor substrate 100 after forming the nitrogen-contained gate dielectric layer 102 as shown in FIG. 4.

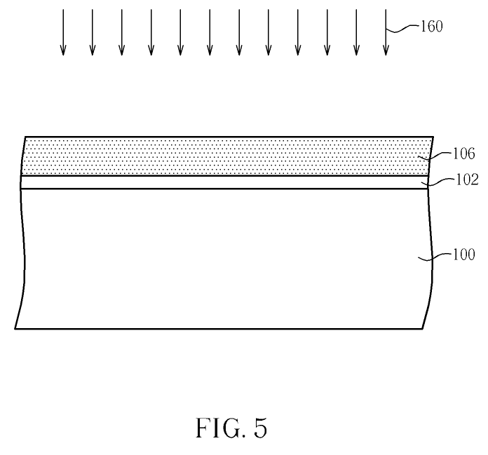

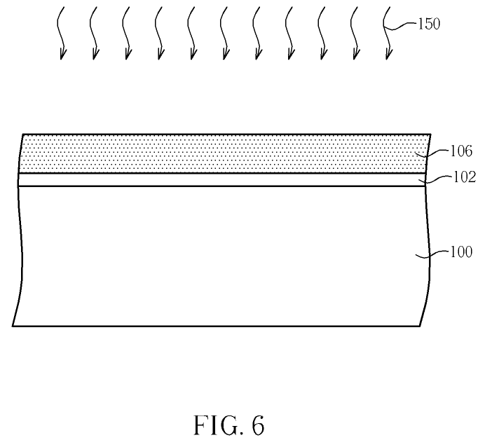

Please refer to FIG. 5. Next, a polysilicon doping process 160 is performed to transfer the polysilicon layer 104 into a doped polysilicon layer 106. It is noteworthy that, in this first preferred embodiment, the thermal treatment 150 can be performed before the polysilicon doping process 160 as mentioned above. On the other hand, the thermal treatment 150 can be performed right after the polysilicon doping process 160, as shown in FIG. 6. Because the lattice in the surface of the semiconductor substrate 100 might be damaged during the polysilicon doping process 160, the thermal treatment 150 performed after the polysilicon doping process 160 is able to repair the lattice of the semiconductor substrate 100 damaged during forming the doped polysilicon layer 106, and further reduces NBTI.

According to the first preferred embodiment of the present invention, the thermal treatment 150 can be a rapid thermal process (RTP) performed at a temperature of 900° C.-1100° C. and in a duration of 1-100 seconds. The thermal treatment 150 can be a laser spike annealing (LSA) process performed at a temperature of 1200° C.-1300° C. and in a duration within 10 milliseconds (ms).

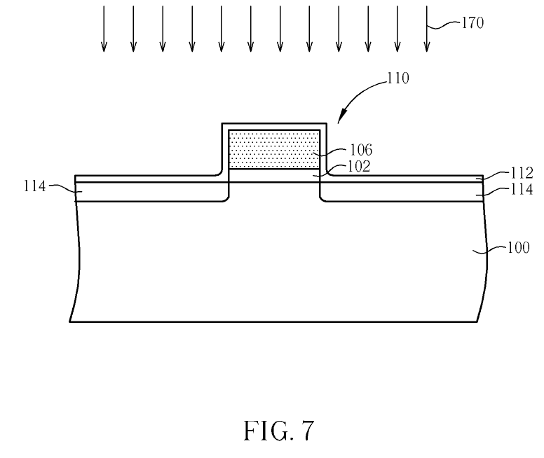

Please refer to FIG. 7. After the thermal treatment 150, an etching process is performed to remove a portion of the nitrogen-contained gate dielectric layer 102 and a portion of the doped polysilicon layer 106 and to form at least a gate 110. It is observed that the etching process also etches the nitrogen-contained gate dielectric layer 102, therefore a re-oxidation process is performed in a furnace or in a rapid thermal process (RTP) chamber with introduced oxygen, such as RTO, for repairing the nitrogen-contained gate dielectric layer 102.

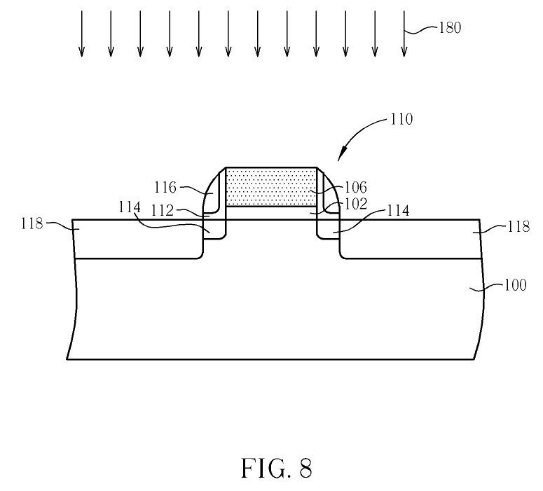

Please refer to FIGS. 7 and 8, then a step of forming a liner 112 on a sidewall of the gate 110 is selectively performed. The liner 112 can be a silicon oxide layer. And a first ion implantation process 170 is performed to form source/drain extension regions 114 in the semiconductor substrate 100 respectively at two sides of the gate 110. Next, a spacer 116 is formed on the sidewall of the gate 110 after the first ion implantation process 170. The spacer 116 can be a silicon oxide layer or a silicon nitride layer. After forming the spacer 116, a second ion implantation process 180 is performed to form a source/drain 118 in the semiconductor substrate 100 respectively at two sides of the gate 110. Such steps or processes are well-known to those skilled in the art, therefore the details are omitted herein in the interest of brevity.

According to the first preferred embodiment of the present invention, the thermal treatment 150 is performed before forming the source/drain extension regions 114, particularly before forming the gate 110 by the etching process. Thus an additional heat is introduced to repair the lattice in the surface of the semiconductor substrate 100 damaged during forming the nitrogen-contained gate dielectric layer 102. The thermal treatment 150 can be performed after forming the nitrogen-contained gate dielectric layer 102 and before the polysilicon doping process 160; the thermal treatment 150 also can be performed right after the polysilicon doping process 160 for further repairing the semiconductor substrate 100 damaged in the polysilicon doping process 160. Therefore, NBTI is effectively improved. Furthermore, because steps of forming the liner 11, the source/drain extension regions 114, the spacer 116, and the source/drain 118 are performed after the thermal treatment 150, and are not modified or influenced in the first preferred embodiment, the heat budget in formation of the source/drain extension regions 114 is not affected, accordingly junction depth and junction profile of the source/drain extension regions 114 is kept from being influenced by additional heat. In other words, methods used to reduce SCE in abovementioned procedures provided by the prior art will not be affected in the first preferred embodiment.

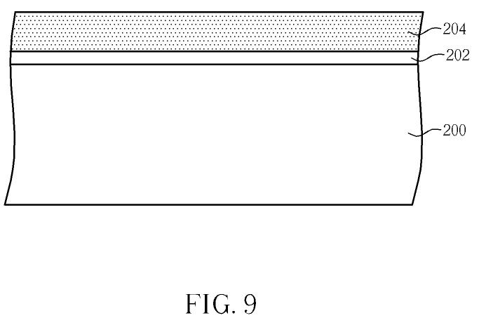

FIGS. 9-13, which are schematic drawings illustrating a method for manufacturing a MOS transistor according to a second preferred embodiment of the present invention. As shown in FIG. 9, a semiconductor substrate 200 having a gate dielectric layer and a polysilicon layer formed thereon is provided. For decreasing current leakage, offering a better barrier to boron, and improving the performance of a transistor, nitrogen is implanted into the gate dielectric layer by a high temperature plasma nitridation process such as DPN, thus a nitrogen-contained gate dielectric layer 202 is obtained. Then the polysilicon layer is transferred into a doped polysilicon layer 204 by a polysilicon doping process.

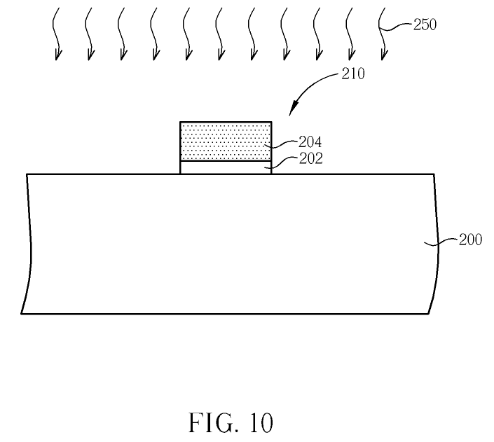

Please refer to FIG. 10, next, an etching process is performed to remove a portion of the nitrogen-contained gate dielectric layer 202 and a portion of the doped polysilicon layer 204 and to form at least a gate 210. Because lattice in surface of the semiconductor substrate 200 is often damaged, interface between the semiconductor substrate 200 and the nitrogen-contained gate dielectric layer 202 is adversely affected in such process, and thus reliability of the MOS transistor is adversely affected due to NBTI. Therefore, a thermal treatment 250 is performed to repair the damaged lattice in the surface of the semiconductor substrate 200 after the gate 210 is formed by the etching process.

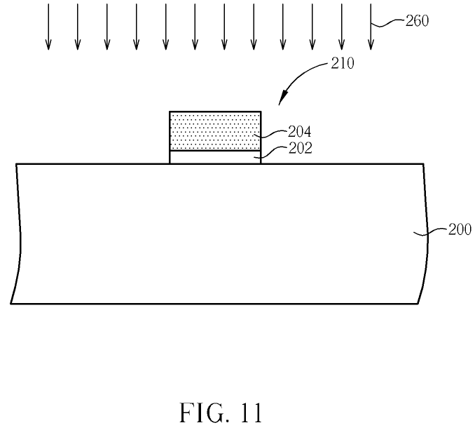

Please refer to FIG. 11. Since the etching process also etches the nitrogen-contained gate dielectric layer 202, a re-oxidation process 260 is performed in a furnace or in a RTP chamber with introduced oxygen, such as RTP, for repairing the nitrogen-contained gate dielectric layer 202. It is noteworthy that, in the second preferred embodiment, the thermal treatment 250 can be performed before the re-oxidation process 260 as mentioned above, it also can be performed after the re-oxidation process 260.

According to the second preferred embodiment of the present invention, the thermal treatment 250 can be a RTP performed at a temperature of 900° C.-1100° C. and in a duration of 1-100 seconds. The thermal treatment 250 can be a LSA process performed at a temperature of 1200° C.-1300° C. and in a duration within 10 ms.

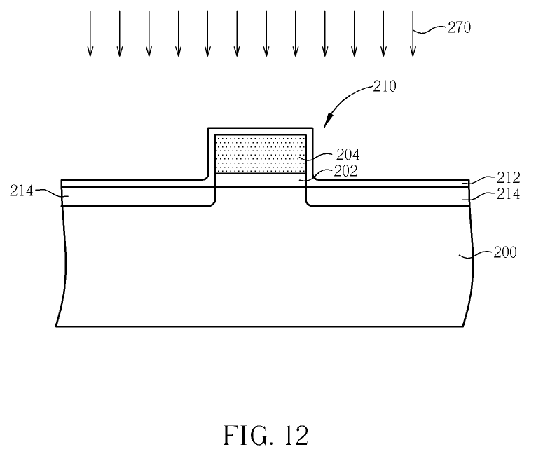

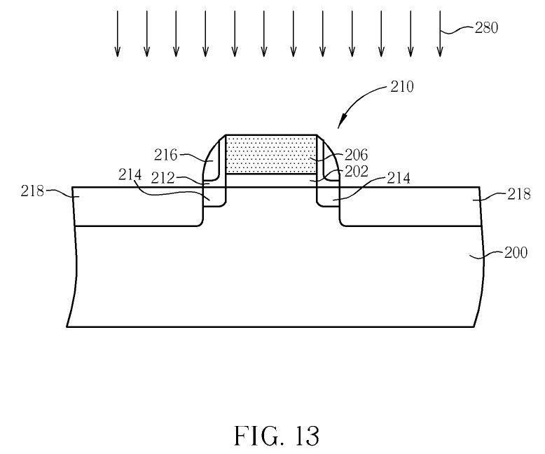

Please refer to FIGS. 12 and 13, then a step of forming a liner 212 on a sidewall of the gate 210 is selectively formed. The liner 212 can be a silicon oxide layer. And a first ion implantation process 270 is performed to form source/drain extension regions 214 in the semiconductor substrate 200 respectively at two sides of the gate 210. Next, a spacer 216 is formed on the sidewall of the gate 210 after performing the first ion implantation process 270. The spacer 216 can be a silicon oxide layer or a silicon nitride layer. After forming the spacer 216, a second ion implantation process 280 is performed to form a source/drain 218 in the semiconductor substrate 200 respectively at two sides of the gate 210. Such steps or processes are well-known to those skilled in the art, therefore the details are omitted herein in the interest of brevity.

According to the second preferred embodiment of the present invention, the thermal treatment 250 is performed after forming the gate 210 by the etching process and before forming the source/drain extension regions 214. Thus an additional heat is introduced to repair the lattice in the surface of the semiconductor substrate 200 damaged during forming the nitrogen-contained gate dielectric layer 202. The thermal treatment 250 can be performed right after the etching process; it also can be performed right after the re-oxidation process 260 used to repair the nitrogen-contained gate dielectric layer 202 damaged in the etching process. Therefore NBTI is effectively improved. Furthermore, because steps of forming the liner 212, the source/drain extension regions 214, the spacer 216, and the source/drain 218 are performed after the thermal treatment 250, and are not modified or influenced in the second preferred embodiment, the heat budget in formation of the source/drain extension regions 214 is not affected, accordingly junction depth and junction profile of the source/drain extension regions 214 is kept from being influenced by additional heat. In other words, methods used to reduce SCE in abovementioned procedures provided by the prior art will not be affected in the first preferred embodiment.

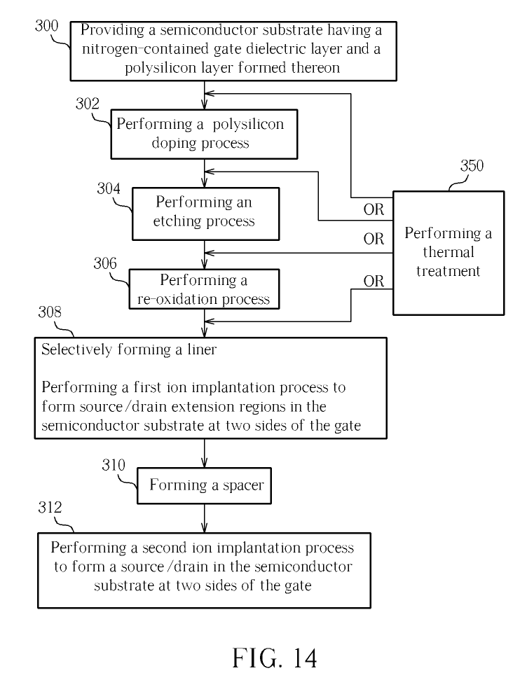

Please refer to FIG. 14, which is a flowchart illustrating a method for manufacturing a MOS transistor provided by the present invention. The method is detailed as follows:

Step 300: Providing a semiconductor substrate having a nitrogen-contained gate dielectric layer and a polysilicon layer formed thereon.

Step 302: Performing a polysilicon doping process to transfer the polysilicon layer into a doped polysilicon layer.

Step 304: Performing an etching process to remove a portion of the nitrogen-contained gate dielectric layer and a portion of the doped polysilicon layer to form at least a gate.

Step 306: Performing a re-oxidation process to repair the nitrogen-contained gate dielectric layer damaged in the etching process.

Step 308: Performing a first ion implantation process to form source/drain extension regions in the semiconductor substrate respectively at two sides of the gate. And a liner is selectively formed on a sidewall of the gate before performing the first ion implantation process.

Step 310: Forming a spacer on the sidewall of the gate.

Step 312: Performing a second ion implantation process to form a source/drain in the semiconductor substrate respectively at the two sides of the gate.

Step 350: Performing a thermal treatment to repair lattice in surface of the semiconductor substrate during forming the nitrogen-contained gate dielectric layer.

As shown in FIG. 14, step 350 can be performed right after Step 300, Step 302, Step 304, or Step 306, respectively. In other words, Step 350 can be performed to repair the damaged lattice in the surface of the semiconductor substrate between any steps before Step 308.

As mentioned above, the method for manufacturing MOS transistor provided by the present invention utilizes a thermal treatment performed before forming the source/drain extension region, in particular, the thermal treatment can be performed right after forming the nitrogen contained gate dielectric layer, after forming the doped polysilicon layer by the polysilicon doping process, after forming gate by the etching process, or after the re-oxidation, respectively. Thus the damaged lattice in the surface of the semiconductor substrate is repaired by the thermal treatment, and NBTI is reduced. Noticeably, since the thermal treatment is performed before forming the source/drain extension regions, the process for forming the source/drain extension regions, heat budget of the process, and junction depth and junction profile of the source/drain extension regions would not be affected. It is seen that methods used to improve SCE in abovementioned steps will not be affected in the present invention. Accordingly the method for forming a MOS transistor provided by the present invention is capable of reducing both of SCE and NBTI and processes a superior process compatibility.

Those skilled in the art will readily observe that numerous modifications and alterations of the device and method may be made while retaining the teachings of the invention.

What is claimed is:

1. A method for manufacturing a MOS transistor, comprising:
providing a semiconductor substrate sequentially having a gate dielectric layer and a polysilicon layer formed thereon;
performing a polysilicon doping process;
performing a thermal treatment;
performing an etching process to remove a portion of the gate dielectric layer and a portion of the polysilicon layer to form at least a gate after the thermal treatment;
performing a first ion implantation process to form source/drain extension regions in the semiconductor substrate respectively at two sides of the gate; and
performing a second ion implantation process to form a source/drain in the semiconductor substrate respectively at the two sides of the gate.

2. The method of claim 1, wherein the gate dielectric layer is a nitrogen-contained gate dielectric layer.

3. The method of claim 1, wherein the thermal treatment is a rapid thermal process (RTP).

4. The method of claim 3, wherein the RTP is performed at a temperature of 900° C.-1100° C.

5. The method of claim 1, wherein the thermal treatment is a laser spike annealing (LSA) process.

6. The method of claim 5, wherein the LSA process is performed at a temperature of 1200° C.-1300° C. and in a duration within 10 milliseconds (ms).

7. The method of claim 1, wherein the thermal treatment is performed before the polysilicon doping process.

8. The method of claim 1, wherein the thermal treatment is performed after the polysilicon doping process.

9. The method of claim 1, further comprising performing a re-oxidation process to repair the gate dielectric layer after the etching process.

10. The method of claim 1, further comprising forming a spacer on a sidewall of the gate after performing the first ion implantation process.

11. The method of claim 10, further comprising forming a liner on sidewall of the gate before performing the first ion implantation process.

12. A method for manufacturing a MOS transistor, comprising:
providing a semiconductor substrate sequentially having a gate dielectric layer and a polysilicon layer formed thereon;
performing an etching process to remove a portion of the gate dielectric layer and a portion of the polysilicon layer to form at least a gate;
performing a re-oxidation process to repair the gate dielectric layer after the etching process;
performing a thermal treatment after the etching process;
performing a first ion implantation process to form source/drain extension regions in the semiconductor substrate respectively at two sides of the gate; and
performing a second ion implantation process to form a source/drain in the semiconductor substrate respectively at the two sides of the gate.

13. The method of claim 12, wherein the gate dielectric layer is a nitrogen-contained gate dielectric layer.

14. The method of claim 12, further comprising performing a polysilicon doping process after the polysilicon layer is provided.

15. The method of claim 12, wherein the thermal treatment is performed after the re-oxidation process.

16. The method of claim 12, wherein the thermal treatment is performed before the re-oxidation process.

17. The method of claim 12, wherein the thermal treatment is a rapid thermal process (RTP).

18. The method of claim 17, wherein the RTP is performed at a temperature of 900° C.-1100° C.

19. The method of claim 12, wherein the thermal treatment is a Laser spike annealing (LSA) process.

20. The method of claim 19, wherein the LSA process is performed at a temperature of 1200° C.-1300° C. and in a duration within 10 milliseconds (ms).
